(19) United States
(12) Patent Application Publication
(10) Pub. No.: US 2004/0084686 A1
(43) Pub. Date: May 6, 2004

(54) Packaging material used for a display device and method of forming thereof

(76) Inventors: Ping-Song Wang, Taipei (TW); Lai-Cheng Chen, Hsinchu (TW); Ming-Shiu Li, Yunlin (TW); Ye-Shiu Li, Yunlin (TW)

Correspondence Address: BIRCH STEWART KOLASCH & BIRCH, PO BOX 747, FALLS CHURCH, VA, 22040-0747, US

(21) Appl. No.: 10/426,628

(22) Filed: May 1, 2003

(30) Foreign Application Priority Data
Nov. 6, 2002 (TW) 091132693

(51) Int. Cl. H01L 33/00

(52) U.S. Cl. 257/99

(57) ABSTRACT

A packaging material used for a display device which is a desiccative-containing adhesive agent. The desiccative-containing adhesive agent is composed of a liquid-state organic material selected from a group including epoxy resin, polyurethane, bakelite, polyamide, acrylic resin and polysiloxane, and a solid-state desiccative selected from a group including alkaline metal oxide, alkaline-earth metal oxide, metallic halide, barium oxide, calcium oxide, calcium sulfate, calcium chloride, lithium chloride, calcium bromide, potassium Carbonate, aluminum oxide, magnesium oxide, copper sulfate, zinc chloride, zinc bromide, cobalt chloride, silica gel, zeolite and molecular sieve.

### BACKGROUND OF THE INVENTION

1. Field of the Invention

The invention relates to a packaging material used for a display device, and more particularly to a packaging material used for an organic electro-luminescence display device.

2. Description of the Related Art

In an electro-luminescence (EL) element used for a display device, electric current applied to specific fluorescence or phosphorus can transform electricity into luminosity. According to the different materials used in the luminescent layer, EL elements are classified as organic and inorganic. In an organic light emitting display (OLED) device, the organic EL element employs laminated organic layers and has the advantages of thin profile, light weight, high luminescent efficiency and low driving voltage. Recently, the OLED device has been highly developed to meet commercial demands in luminescent efficiency, optical-electrical characteristics, and mass production. In order to prolong the active lifetime and improve reliability, novel technologies for packaging the OLED device are called for.

The organic EL element employs active metal of low work function to form the cathode layer, thus the active lifetime is affected by the content of moisture and oxygen existing inside the organic EL element. As the duration of use increases, the probability of moisture and oxygen permeating the organic EL element also increases, causing detachment between the organic luminescent layer and the cathode electrode, cracking of the organic materials, and oxidation of the electrodes. As a result, a so-called ‘dark spot’, to which electricity is not supplied, occurs, decreasing luminescence and luminescent uniformity. The causes of moisture inside the organic EL element are as follows. First, imperfections in the packaging process make the exterior environmental elements, such as moisture and oxygen to permeate the interior space of the OLED device through defects. Second, an interface of insufficient bonding strength between the packaging material and the substrate makes the exterior moisture permeate into the interior of the organic EL element. Third, the packaging material itself contains moisture, which is released in the packaging process and throughout the duration of use. Fourth, by a mechanism of diffusion, the exterior moisture permeates the interior space of the organic EL element.

Various technologies of reducing interior humidity, and correct the dark spot problem, exist, such as forming photo-hardened resin on the glass substrate, plating metal oxide, fluoride or sulfide on the glass substrate, forming a moisture-resistant film on the glass substrate, and using an airtight case to package the organic EL element. Nevertheless, other problems, such as current leakage, crosstalk, and oxide dissolution occur.

FIG. 1 is a sectional diagram of a first package structure of an organic EL element 10 according to a conventional OLED device. The organic EL element 10 comprises a glass substrate 12, a sealing agent 16 of UV-curing resin formed on the rim of the glass substrate 12, and a sealing case 18 bonded to the glass substrate 12 by the sealing agent 16. Thus, the internal space 19 formed by the glass substrate 12 and the sealing case 18 becomes an airtight container. Also, in the airtight container, the glass substrate 12 comprises a lamination body 14 that is formed by a cathode layer 15, an organic luminescent material layer 13 and an anode layer 11.

The UV-curing resin used in the sealing agent 16, however, is epoxy resin, and offers poor resistance to moisture in the internal space 19 caused by outgassing of the sealing agent 16 and the permeation of moisture and oxygen from the atmosphere. This may compromise the luminescent properties of the organic EL element 10, and may disable the organic EL element 10 from meeting the demands of environmental-measuring tests.

FIG. 2 is a sectional diagram of a second package structure of an organic EL element 20 according to a conventional OLED device. In Comparison, the sealing case 18 in the first package structure is modified as a stamping-type metal case 22 in the second package structure in which a concave portion is formed on the inner sidewall corresponding to the lamination body 14. Also, a moisture-absorbing film 24 of a solid compound, such as BaO, CaO, CaSO4, CaCl2, silicon, zeolite, and molecular sieve, is placed within the concave portion to chemically absorb moisture and maintain its solid state. Moreover, the moisture-absorbing film 26 is covered by a one-directional permeable film 26 to prevent the moisture absorbed by the moisture-absorbing film 24 from permeating the internal space 19. This ensures that the organic EL element 20 meets the strict demands of environmental-measuring tests.

Some difficulties found during disposing the desiccative substance inside the organic EL element 20 are as follows. First, the powder-form desiccative substance must employ a solvent as the carrier so as to successively fill in the organic EL element and then the solvent must be removed by heating. Second, the organic luminescent body is sensitive to heat and residual solvent, thus the above-described solvent and heating may damage the organic EL element. Third, for a desiccative substance of high moisture absorption rate, such as zeolite, water-removing and activation steps at more than 250° C. are needed in pre-processing, thus the packaging procedure is complicated. Fourth, the uneven profile of the metal case 22 may generate interstices in the package structure, and the metal case 22 applied to a large-size OLED device encounters difficulties in manufacturing a large-size metal case. Fifth, since the metal case 22 is thicker than the glass substrate 12, the organic EL element 20 cannot meet commercial demands of lightweight, relatively thin profile, and small size.

Various technologies, to provide the powder-form drying substance into an electronic device, have been developed. U.S. Pat. No. 5,304,419 discloses an enclosure of an inner surface coated with a pressure sensitive adhesive which comprises a solid desiccative. U.S. Pat. No. 5,591,379 discloses a composition of moisture absorbing properties in which a desiccative is finely dispersed in a binder of water vapor permeable solid material, and the binder is polymer, porous glass, or porous ceramic. U.S. Pat. No. 6,226,890 discloses a method of sealing an electronic device, in which a blend including desiccative particles and a liquid binder that maintains or enhances the moisture absorption of the desiccative particle is cast onto the inner surface of an enclosure and then solidified. U.S. Pat. No. 4,013,566 discloses a flexible solid desiccative body comprised of finely divided particles of desiccative material, such as molecular sieve, homogeneously distributed, and bound in a moisture transmissive aliphatic epoxy polymer matrix. U.S. Pat. No. 4,036,360 discloses a desiccative composition in which desiccative particles are distributed in pre-polymerized polyurethane resin with a high moisture vapor transmission rate. Nevertheless, other problems are generated in the above-described modifications. First, several steps are added to introduce the desiccative particles and the carrier into the display device and then solidify the desiccative layer. Second, the vapor absorption rate of the desiccative layer varies depending on the type of desiccative substance, temperature and vapor diffusion rate, thus the moisture damages the organic EL element before the desiccative layer completely absorbs the moisture.

### SUMMARY OF THE INVENTION

The present invention is a packaging material used for a display device to achieve high adhesive strength, low moisture-containing content, low moisture-permeating rate, and the capability to absorb moisture, oxygen, or harmful substances.

Accordingly, the present invention provides a packaging material used for a display device which is a desiccative-containing adhesive agent. The desiccative-containing adhesive agent is composed of a liquid-state organic material selected from a group including epoxy resin, polyurethane, bakelite, polyamide, acrylic resin and polysiloxane, and a solid-state desiccative selected from a group including alkaline metal oxide, alkaline-earth metal oxide, metallic halide, barium oxide, calcium oxide, calcium sulfate, calcium chloride, lithium chloride, calcium bromide, potassium Carbonate, aluminum oxide, magnesium oxide, copper sulfate, zinc chloride, zinc bromide, cobalt chloride, silica gel, zeolite and molecular sieve.

Accordingly, the present invention also provides a packaging material used for a display device which is a desiccative-containing adhesive agent. The desiccative-containing adhesive agent is a blend of an epoxy resin adhesive agent and a powder-type desiccative. The epoxy resin adhesive agent is a thermosetting epoxy resin adhesive agent which is a blend including epoxy resin of 100 g, a hardening agent of amine of 1˜100 g, an anti-depositing agent of 0˜5 g, an antifoam agent of 0.01˜1 g, a multi-functional acrylic monomer of 3˜5 g, and a photoinitiator of 0˜1 g. Alternatively, the epoxy resin adhesive agent is a light-hardening epoxy resin adhesive agent which is a blend including epoxy resin of 100 g, polyols of 0˜50 g, a light-hardening photoinitiator of 0.110 g, an antifoam agent of 0.01˜1 g, a multi-functional acrylic monomer of 3˜5 g and a photoinitiator of 0.1˜1 g. The powder-type desiccative is selected from a group including alkaline metal oxide, alkaline-earth metal oxide, metallic halide, barium oxide, calcium oxide, calcium sulfate, calcium chloride, lithium chloride, calcium bromide, potassium Carbonate, aluminum oxide, magnesium oxide, copper sulfate, zinc chloride, zinc bromide, cobalt chloride, silica gel, zeolite and molecular sieve. The particle diameter of the desiccative is 0.1˜200 μm and the weight fraction of the desiccative in the desiccative-containing adhesive agent is 10%-70%.

### DESCRIPTION OF THE DRAWINGS

For a better understanding of the present invention, reference is made to a detailed description to be read in conjunction with the accompanying drawings.

FIG. 1 is a sectional diagram of a first package structure of an organic EL element according to a conventional OLED device.

FIG. 2 is a sectional diagram of a second package structure of an organic EL element according to a conventional OLED device.

FIG. 3 is a flowchart of a method of forming the packaging material according to the first embodiment of the present invention.

FIG. 4 is a flowchart of a method of forming the packaging material according to the first embodiment of the present invention.

FIG. 5 is an electron microscope diagram showing the package structure of the organic EL display device that has performed normally after an environmental test at 60° C., 90% RH for 500 hours.

FIG. 6 is an electron microscope diagram showing the package structure of the organic EL display device can absorbs moisture through the packaging material after an environmental test at 60° C., 90% RH for 500 hours.

FIG. 7 is an electron microscope diagram showing a conventional package structure of the organic EL display device without the desiccative-containing adhesive agent coating eroded by moisture after an environmental test at 60° C., 90% RH for 500 hours.

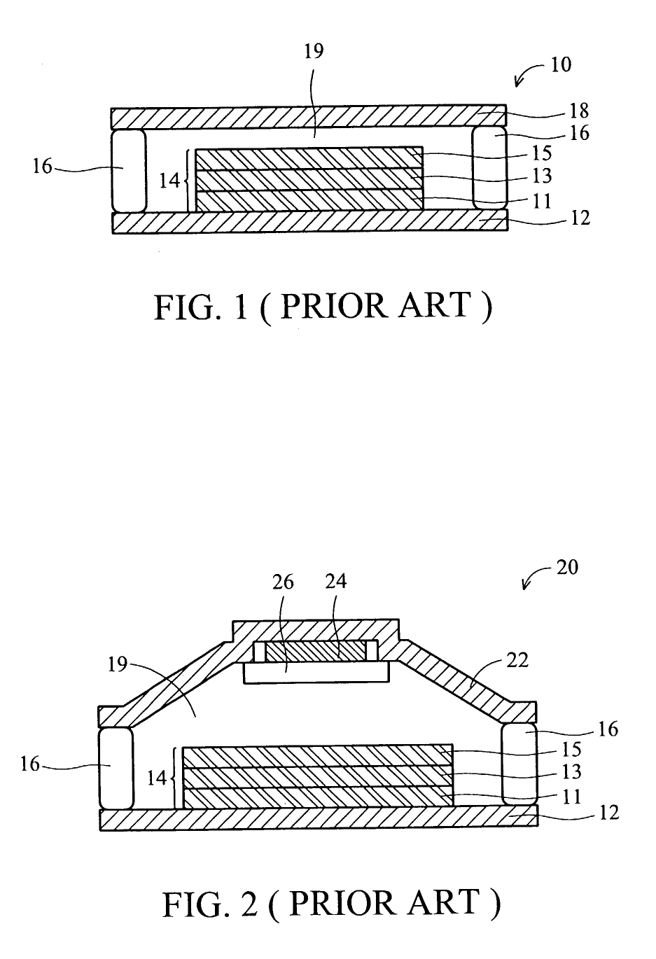

### DETAUKED DESCRIPTION OF THE INVENTION

The present invention provides a packaging material used for an organic EL element or an inorganic EL element which is applied to a display device including OLED device, polymer light emitting diode (PLED) device, liquid crystal display (LCD) device, plasma display panel (PDP) device and other light emitting diode (LED) device. Also, the packaging material may be formed as a single-layered structure, a dual-layered structure or a multi-layered structure. The packaging material is inside the package structure, at the peripheral portion surrounding the luminescent body or envelops the luminescent body. Furthermore, a barrier rib structure, a vapor-protection, or water-resistant film can be formed in the package structure of the EL element to improve the active lifetime of the display device.

The packaging material can be pre-polymerized under ultraviolet or visible light to increase viscosity thereof, thus ensuring the reliability of the package process without deforming the packaging material layer. The packaging material has the characteristics of high linking strength, low moisture content and low moisture-permeation rate, and the ability to absorb moisture, oxygen and other adverse substances, thus effectively avoiding the permeation of moisture and oxygen and increasing the active lifetime of the display device. The packaging material is an adhesive agent, a blend of liquid-state organic material and solid-state desiccative, which has room-temperature curing, thermosetting, violet curing, or visible-light curing properties. The liquid-state organic material may be epoxy resin, polyurethane, bakelite, polyamide, acrylic resin or polysiloxane, and a film of 100 μm thickness formed by curing liquid-state organic material that has a moisture-permeation rate less than 10 g/m2*24 hr. The solid-state desiccative may be alkaline metal oxide, alkaline-earth metal oxide, metallic halide, barium oxide, calcium oxide, calcium sulfate, calcium chloride, lithium chloride, calcium bromide, potassium Carbonate, aluminum oxide, magnesium oxide, copper sulfate, zinc chloride, zinc bromide, cobalt chloride, silica gel, zeolite or molecular sieve. The weight fraction of the solid-state desiccative of 0.1˜200 μm diameter in the blend is in a range 10%-70%.

First Embodiment

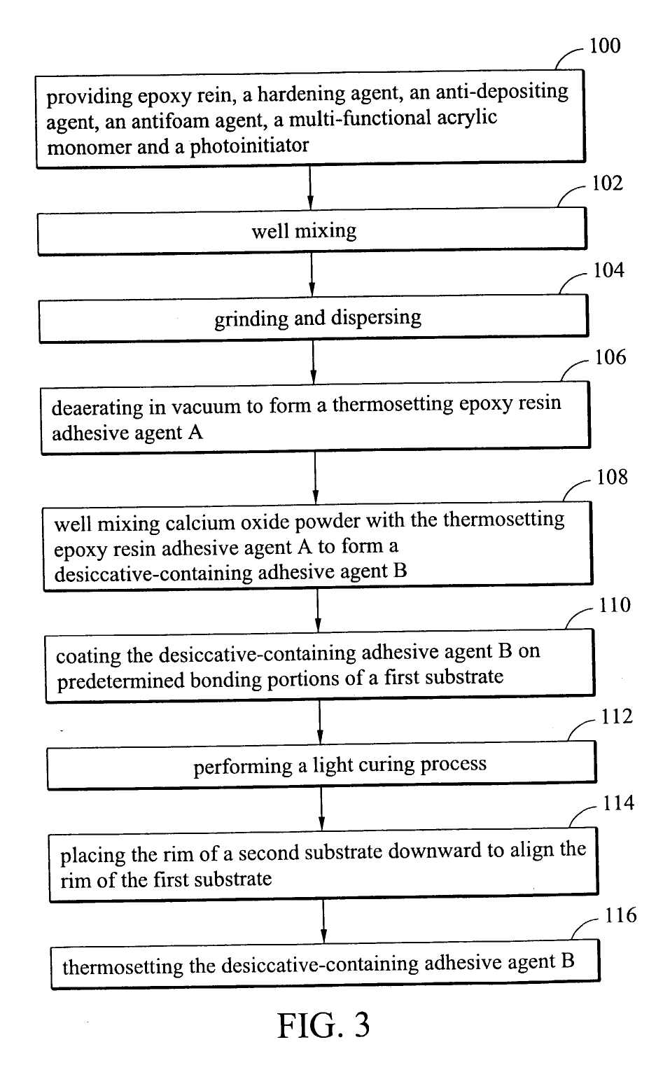

FIG. 3 is a flowchart of a method of forming the packaging material according to the first embodiment of the present invention.

First, at step 100, a bisphenol A glycidyl ether-based epoxy resin of 100 g in weight, a hardening agent of amine of 110 g in weight, an anti-depositing agent of melted silica of 0.1˜5 g in weight, a silicon-based antifoam agent of 0.01˜1 g in weight, a multi-functional acrylic monomer of 3˜5 g in weight, and a photoinitiator of 0.11 g in weight are provided.

For example, the epoxy resin of 100 g in weight is model DER331 produced by Dow Chemical Co. in America, the hardening agent of 25 g in weight is model PN23 produced by Ajinomoto fine-techno Co. Inc. in Japan, the anti-depositing agent of 1 g in weight is model Aerosil 380 produced by Degussa-Huis Co. in Germany, the antifoam agent of 0.5 g in weight is model Airex 900 produced by Tego Co. in Germany, the multi-functional acrylic monomer of 5 g in weight is model SR351 produce by Sartomer. Co. Inc. in America, and the photoinitiator of 1 g is model Irgacure 1173 produced by Ciba Specialty Chemical Inc. in Switzerland.

Then, at step 102, the above-described materials are well mixed by an agitator. Next, at step 104, the above-described materials are ground and dispersed from three rollers. Next, at step 106, the above-described materials are deareated in a 1 mm-Hg vacuum for 8 hours, resulting in a thermosetting epoxy resin adhesive agent A capable of pre-reaction in a subsequent light curing process. Next, as step 108, calcium oxide powder of 5 μm in diameter and 30 g in weight is provided to be well mixed with the thermosetting epoxy resin adhesive agent A of 70 g in weight, resulting in a desiccative-containing adhesive agent B which serves as a packaging material of the first embodiment of the present invention.

Thereafter, at step 110, in a N₂-containing chamber with water content less than 10 ppm, the desiccative-containing adhesive agent B is coated on predetermined bonding portions of a first substrate of an organic EL display device. Then, at step 112, in a light curing process, the desiccative-containing adhesive agent B coated on the first substrate is exposed to a violet of 254 nm wavelength and 100 mW/cm² illumination for 60 seconds. Next, at step 114, a second substrate is provided, and the rim of the second substrate is placed downward and aligned to the rim of the first substrate. Finally, at step 116, in a thermosetting process, the desiccative-containing adhesive agent B sandwiched between the first substrate and the second substrate is heated at 80° C. for 1 hour to cure the desiccative-containing adhesive agent B, thus a package structure of the organic EL display device is completed.

Second Embodiment

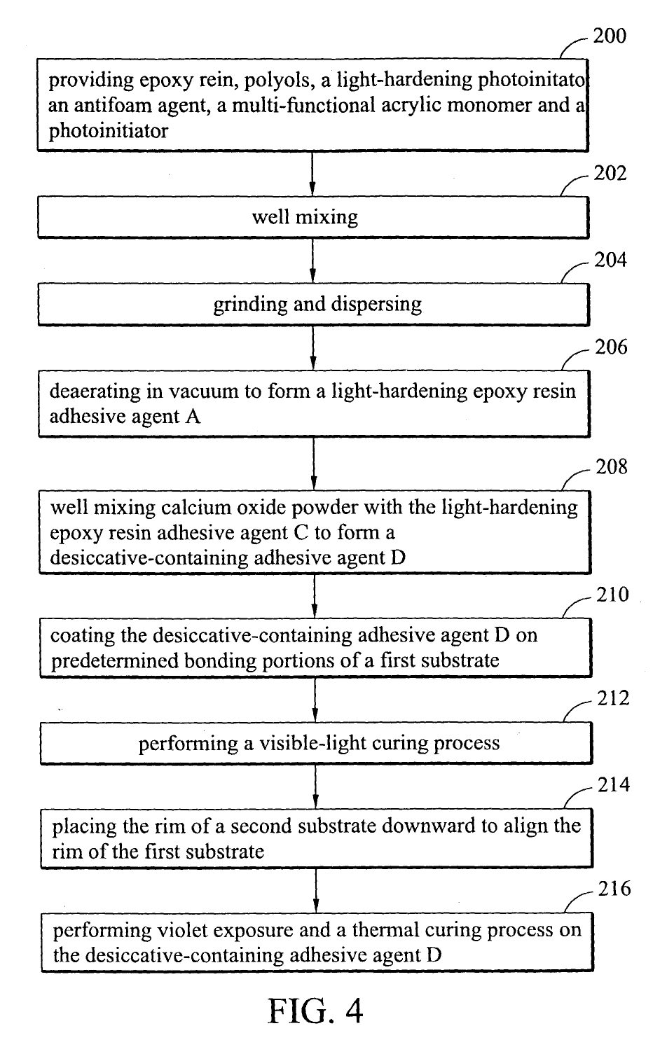

FIG. 4 is a flowchart of a method of forming the packaging material according to the first embodiment of the present invention.

First, at step 200, bisphenol F glycidyl ether based epoxy resin of 100 g in weight, polypropylene oxide based polyols of 0˜50 g in weight, a light-hardening photoinitiator of 0.1˜10 g in weight generated by triphenyl sulfide and phosphorus hexafluoride, a silicon-based antifoam agent of 0.01˜1 g in weight, a multi-functional acrylic monomer of 3˜5 g in weight, and a photoinitiator of 0.1˜1 g in weight are provided.

For example, the epoxy resin of 100 g in weight is model EPON862 produced by Resolution Performance Products LLC. in America, polyols of 5 g in weight is model 1048 produced by Lyondell Chemical Co. in Taiwan, the light-hardening photoinitiator of 4 g in weight is model SP150 produced by ASAHI DENKA Co. Ltd in Japan, the antifoam agent of 0.5 g in weight is model Airex 900 produced by Tego Co. in Germany, the multi-functional acrylic monomer of 5 g in weight is model Photomer3016 produce by Henkel Corporation in America, and the photoinitiator of 1 g is model LR8893 produced by BASF Aktiengesellschaft in Germany.

Then, at step 202, the above-described materials are well mixed by an agitator. Next, at step 204, the above-described materials are ground and dispersed from three rollers. Next, at step 206, the above-described materials are deareated in a 1 mm-Hg vacuum for 8 hours, resulting in a light-hardening epoxy resin adhesive agent C which can have a pre-reaction under visible light of a great wavelength and curing is then complete under violet light of a short wavelength in the subsequent processes. Next, as step 208, calcium oxide powder of 5 μm in diameter and 30 g in weight is provided to be well mixed with the light-hardening epoxy resin adhesive agent C of 70 g in weight, resulting in a desiccative-containing adhesive agent D which serves as a packaging material of the second embodiment of the present invention.

Thereafter, at step 210, in a N2-containing chamber with water content less than 10 ppm, the desiccative-containing adhesive agent D is coated on predetermined bonding portions of a first substrate of an organic EL display device. Then, at step 212, in a light curing process, the desiccative-containing adhesive agent B coated on the first substrate is disposed under a visible light of 436 nm wavelength and 100 mW/cm2 illumination for 20 seconds. Next, at step 214, a second substrate is provided, and the rim of the second substrate is placed downward and aligned to the rim of the first substrate. Finally, at step 216, in a thermal curing process, the desiccative-containing adhesive agent D sandwiched between the first substrate and the second substrate is exposed under violet of 365 nm wavelength and then heated at 80° C. for 1 hour to cure the desiccative-containing adhesive agent D, thus a package structure of the organic EL display device is completed.

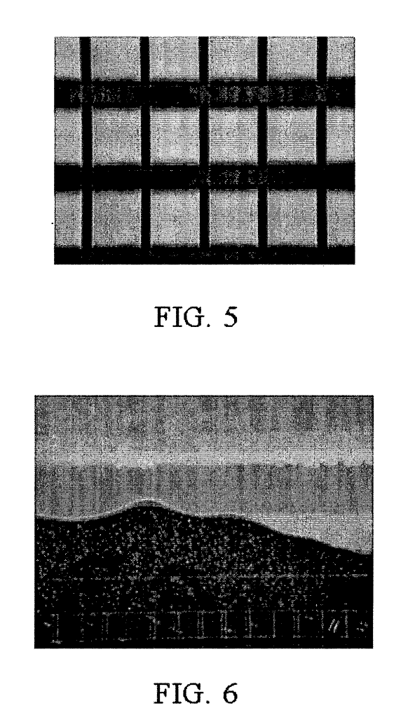

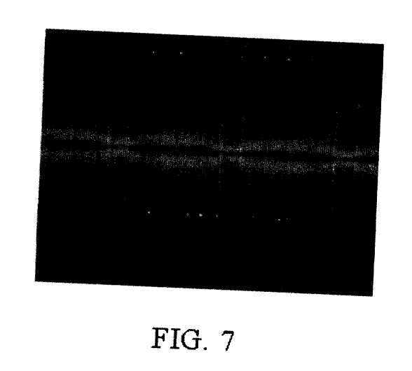

FIG. 5 is an electron microscope diagram that shows the above-described package structure of the organic EL display device that performs normally after an environmental test at 60° C., 90% RH for 500 hours. FIG. 6 is an electron microscope diagram that shows the above-described package structure of the organic EL display device can absorb moisture by the packaging material after an environmental test at 60° C., 90% RH for 500 hours. FIG. 7 is an electron microscope diagram that shows a conventional package structure of the organic EL display device without the coating of desiccative-containing adhesive agent B or D is eroded by moisture after an environmental test at 60° C., 90% RH for 500 hours.

The moisture-absorption content of the packaging material is recognized from the appearance of the display device and depends on the additive quantity of the desiccatives. Thus, the active lifetime of the display device can achieve demands for merchandise by precisely controlling the amount of the desiccatives added to the packaging material and the bonding width of the package structure.

Compared with the conventional package structure, the packaging material used for a display device has the following advantages. First, the processes of preparing the packaging material are simplified. Since the desiccatives are mixed with the adhesive agent in the packaging material, the moisture-absorption problem caused by the desiccatives prior to the packaging procedure is prevented, an extra heating step for eliminating water from the desiccatives is unnecessary, and the complicated techniques for disposing powder-type desiccatives inside the device are avoided. Second, the processes of packaging the display device are facilitated. The light curing process, serving as a pre-action, increases the viscosity of the desiccative-containing adhesive agent before pressing and aligning the rims of the two substrates, thus preventing the desiccative-containing adhesive agent from running, squeezing and spilling. Third, the present invention provides one layer of the desiccative-containing adhesive agent directly coated within the package structure without further employing a solvent as the carrier. Thus, several steps for introducing the desiccative particles and the carrier into the display device and then solidifying the desiccative layer are omitted. Fourth, the packaging material provides high reliability. The desiccatives are mixed with adhesive agent before coating the packaging material and pressing the two substrates, thus the moisture can be completely absorbed by the packaging material without permeating into the display device before the package structure is completed.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A packaging material used for a display device comprising a desiccative-containing adhesive agent, in which the desiccative-containing adhesive agent is composed of:
a liquid-state organic material selected from a group including epoxy resin, polyurethane, bakelite, polyamide, acrylic resin and polysiloxane; and
a solid-state desiccative selected from a group including alkaline metal oxide, alkaline-earth metal oxide, metallic halide, barium oxide, calcium oxide, calcium sulfate, calcium chloride, lithium chloride, calcium bromide, potassium Carbonate, aluminum oxide, magnesium oxide, copper sulfate, zinc chloride, zinc bromide, cobalt chloride, silica gel, zeolite and molecular sieve.

2. The packaging material used for a display device of claim 1, wherein the particle diameter of the desiccative is 0.1˜200 μm and the weight fraction of the desiccative in the desiccative-containing adhesive agent is 10%-70%.

3. The packaging material used for a display device of claim 1, wherein the liquid-state organic material has a moisture-permeation rate less than 10 g/m2*24 hr per 100 μm thickness after a curing process.

4. The packaging material used for a display device of claim 1, wherein the desiccative-containing adhesive agent has room-temperature curing, thermosetting, a violet curing, or visible-light curing properties.

5. The packaging material used for a display device of claim 1, wherein the display device is an organic light emitting diode (OLED) device, a polymer light emitting diode (PLED) device, a liquid crystal display (LCD) device, a plasma display panel (PDP) device.

6. A packaging material used for a display device comprising a desiccative-containing adhesive agent, in which the desiccative-containing adhesive agent is a blend of:
an epoxy resin adhesive agent; and
a powder-type desiccative.

7. The packaging material used for a display device of claim 6, wherein the epoxy resin adhesive agent is a thermosetting epoxy resin adhesive agent which is a blend including epoxy resin of 100 g, a hardening agent of amine of 1˜100 g, an anti-depositing agent of 0.1˜5 g, an antifoam agent of 0.01˜1 g, a multi-functional acrylic monomer of 3˜5 g, and a photoinitiator of 0˜1 g.

8. The packaging material used for a display device of claim 6, wherein the epoxy resin adhesive agent is a light-hardening epoxy resin adhesive agent which is a blend including epoxy resin of 100 g, polyols of 0˜50 g, a light-hardening photoinitiator of 0.1˜10 g, an antifoam agent of 0.01˜1 g, a multi-functional acrylic monomer of 3˜5 g and a photoinitiator of 0˜1 g.

9. The packaging material used for a display device of claim 6, wherein the a powder-type desiccative is selected from a group including alkaline metal oxide, alkaline-earth metal oxide, metallic halide, barium oxide, calcium oxide, calcium sulfate, calcium chloride, lithium chloride, calcium bromide, potassium Carbonate, aluminum oxide, magnesium oxide, copper sulfate, zinc chloride, zinc bromide, cobalt chloride, silica gel, zeolite and molecular sieve.

10. The packaging material used for a display device of claim 6, wherein the particle diameter of the desiccative is 0.1˜200 m and the weight fraction of the desiccative in the desiccative-containing adhesive agent is 10%-70%.

11. The packaging material used for a display device of claim 6, wherein the display device is an organic light emitting diode (OLED) device, a polymer light emitting diode (PLED) device, a liquid crystal display (LCD) device, a plasma display panel (PDP) device.

12. A method of forming a packaging material used for a display device, comprising steps of:
providing an organic material including epoxy resin, a hardening agent, an anti-depositing agent of 0.1˜5 g, an antifoam agent, a multi-functional acrylic monomer, and a photoinitiator;
thoroughly mixing the organic material;
grinding and dispersing the organic material;
deaerating the organic material in a vacuum to form a thermosetting epoxy resin adhesive agent; and
thoroughly mixing a calcium oxide powder with the thermosetting epoxy resin adhesive agent to form a desiccative-containing adhesive agent.

13. The method of forming a packaging material used for a display device of claim 12, wherein the organic material comprises epoxy resin of 100 g, a hardening agent of amine of 1˜100 g, an anti-depositing agent of 0.1˜5 g, an antifoam agent of 0.01˜1 g, a multi-functional acrylic monomer of 3˜5 g, and a photoinitiator of 0.11 g.

14. The method of forming a packaging material used for a display device of claim 12, wherein the calcium oxide powder of 5 μm diameter and 30 g in weight is provided to be well mixed with the thermosetting epoxy resin adhesive agent of 70 g in weight.

15. A method of forming a packaging material used for a display device, comprising steps of:
providing an organic material including epoxy resin, polyols, a light-hardening photoinitiator, an antifoam agent, a multi-functional acrylic monomer and a photoinitiator;
thoroughly mixing the organic material;
grinding and dispersing the organic material;
deaerating the organic material in vacuum to form a light-hardening epoxy resin adhesive agent; and
thoroughly mixing a calcium oxide powder with the light-hardening epoxy resin adhesive agent to form a desiccative-containing adhesive agent.

16. The method of forming a packaging material used for a display device of claim 15, wherein the organic material comprises epoxy resin of 100 g, polyols of 0˜50 g, a light-hardening photoinitiator of 0.110 g, an antifoam agent of 0.01˜1 g, a multi-functional acrylic monomer of 3˜5 g and a photoinitiator of 0.1˜1 g.

17. The method of forming a packaging material used for a display device of claim 16, wherein the calcium oxide powder of 5 μm diameter and 30 g in weight is provided to be well mixed with the light-hardening epoxy resin adhesive agent of 70 g in weight.
